(19) United States
(12) Patent Application Publication
(10) Pub. No.: US 2014/0197898 A1
(43) Pub. Date: Jul. 17, 2014

(54) High Sensitivity Micro-Piezoelectric Tunable Resonator

(71) Applicants: Ying Hsu, Costa Mesa, CA (US); Mike Tracy, Aliso Viejo, CA (US); Brian Bircumshaw, Costa Mesa, CA (US); Ning Chen, Emeryville, CA (US); Salah Uddin, Emeryville, CA (US)

(72) Inventors: Ying Hsu, Costa Mesa, CA (US); Mike Tracy, Aliso Viejo, CA (US); Brian Bircumshaw, Costa Mesa, CA (US); Ning Chen, Emeryville, CA (US); Salah Uddin, Emeryville, CA (US)

(21) Appl. No.: 13/744,064

(22) Filed: Jan. 17, 2013

(51) Int. Cl. H03B 5/32

(52) U.S. Cl. CPC H03B 5/32
USPC 331/155

(57) ABSTRACT

A highly sensitive micro-piezoelectric tunable resonator element and device that uses a tapered transition region from the actuator and sensor elements to the resonator beam to permit maximum mechanical energy transfer to the beam. A dual-resonator beam embodiment with a shared tuning element is provided in an alternative embodiment.

### CROSS-REFERENCE TO RELATED APPLICATIONS

This application claims the benefit of U.S. Provisional Patent Application No. 61/587,151 filed on Jan. 17, 2012 entitled “High Sensitivity Tunable Resonator” pursuant to 35 USC 119, which application is incorporated fully herein by reference.

### STATEMENT REGARDING FEDERALLY SPONSORED RESEARCH AND DEVELOPMENT

This invention was made with United States Government support under Contract No. W909MY-10-C-0022 awarded by Army Night Vision Electronic Sensors Directorate (NVESD). The United States Government has certain rights in the invention.

### BACKGROUND OF THE INVENTION

1. Field of the Invention

The invention relates generally to the field of inertial measurement devices. More specifically, the invention relates to a highly sensitive micro-piezoelectric tunable resonator element and device.

2. Description of the Related Art

Existing micro-resonator elements utilize a wide range of methods for actuation and sensing. Some of the methods used for generating actuation forces include piezoelectric, electrostatic, thermal, and magnetic effects. These same methods used for resonator actuation are also used for sensing the resonator movement. In resonant sensors, changes in the resonant frequency or phase are commonly used to determine or sense changes in the parameter of interest.

New resonant sensor development continues to strive for higher sensitivity. What is needed is a resonant sensor element with very high sensitivity but that can be fabricated at low cost using known semiconductor foundry processes.

### BRIEF SUMMARY OF THE INVENTION

A highly sensitive micro-piezoelectric tunable resonator element and device is disclosed that comprises a tapered transition region from the actuator or sensor elements, or both, to and from the resonator beam to permit maximum mechanical energy transfer to and from the beam. A dual-resonator beam embodiment with a shared tuning element is also provided in an alternative embodiment.

In a first aspect of the invention, a tunable resonator is provided comprising a first terminal portion, a resonant actuator element, a sensor element, a resonator beam in mechanical connection with the resonant actuator element and the sensor element, and, a second terminal portion.

In a second aspect of the invention the tunable resonator comprise a transition region between the resonator beam and the resonant actuator element or the sensor element is tapered.

In a third aspect of the invention, the transition region comprises a predetermined angle defined by a linear edge of the resonator beam and the resonant actuator or sensor element.

In a fourth aspect of the invention, the transition region comprises a predetermined radius defined by the edge of the resonator beam and the edge of the resonant actuator element or sensor element.

In a fifth aspect of the invention, a tunable resonator is provided comprising a base substrate, a first terminal portion, a resonant actuator element, a sensor element, a resonator beam, a tuning actuator element, and, a second terminal portion.

In a sixth aspect of the invention, a transition region is provided between the resonator beam and the resonant actuator element or the sensor element that is tapered.

In a seventh aspect of the invention, the transition region comprises a predetermined angle.

In an eighth aspect of the invention, the transition region comprises a predetermined radius.

In a ninth aspect of the invention, a dual-beam tunable resonator is provided comprising a plurality of resonant actuator elements, a plurality of sensor elements, a plurality of resonator beams, and, a shared tuning actuator configured to permit the common tuning of a resonant frequency of the plurality of resonator beams.

In a tenth aspect of the invention, a transition region is provided between at least one resonator beam and at least one of the resonant actuator elements or the sensor elements that is tapered.

In an eleventh aspect of the invention, at least one of the transition regions comprises a predetermined angle.

In a twelfth aspect of the invention, at least one of the transition regions comprises a predetermined radius.

In a thirteenth aspect of the invention, the tunable resonator further comprises differential amplifier circuitry configured for the differential sensing of the outputs of a plurality of sensor elements.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### BRIEF DESCRIPTION OF THE SEVERAL VIEWS OF THE DRAWINGS

FIG. 1 depicts a preferred embodiment of a tunable resonator element of the invention.

FIG. 2 and Table 1 illustrates a cross-section of a preferred embodiment of a tunable resonator of the invention and a table illustrating the materials of each layer.

FIG. 3 depicts exemplar dimensions and geometries for a preferred embodiment of a resonator element of invention.

FIG. 4 depicts a preferred embodiment of a tunable resonator of the invention comprising a square electrode element.

FIG. 5 depicts a preferred embodiment of a tunable resonator of the invention comprising a tapered electrode element.

FIG. 6 depicts an alternative preferred embodiment of a tunable resonator of the invention comprising a tapered electrode element.

FIG. 7 depicts a preferred embodiment of a dual-beam tunable resonator of the invention comprising a plurality of tapered electrode elements.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

Turning now to the figures wherein like references define like elements among the several views, Applicants disclose a high sensitivity micro-piezoelectric tunable resonator. A novel, tapered resonator electrode design for high sensitivity output is disclosed. The invention comprises a micro-resonant structure that functions as a transducer element or a plurality of transducer elements in an electronic sensor well-suited for electronic measurement of physical, chemical, electrical, optical, and biological events.

In the field of inertial sensors (e.g., gyroscopes and accelerometers), a common method to increase sensitivity is the use of a relatively large proof mass operating in cooperation with a transducer element that in turn has a relatively small cross-section.

By using a relatively thick proof mass in the inertial sensor along with a relatively thin transducer element, the resulting large ratio of the proof mass thickness-to-resonator thickness results in high output sensitivity.

For example, to increase sensitivity of micro-gyroscopes and micro-accelerometers, a proof mass of over 100 microns thick may be combined with a transducer element with a thickness of one micron or less. The 100:1 thickness ratio desirably increases the sensitivity of the sensor by a factor of approximately 100 as compared to a sensor with a proof mass-to-transducer thickness ratio of 1:1.

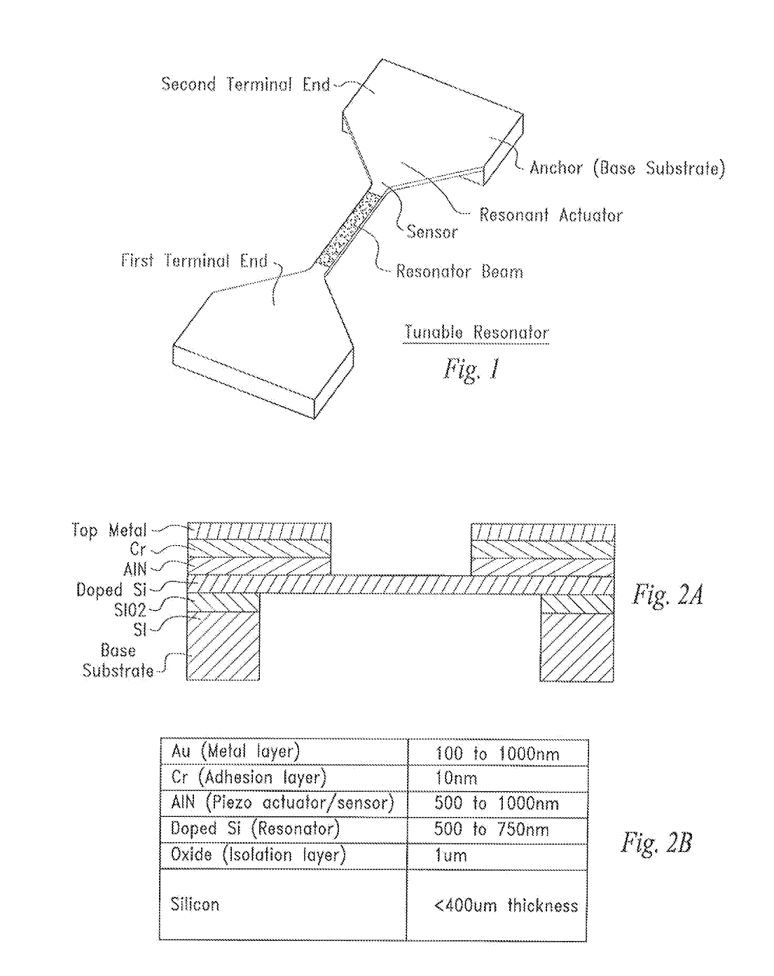

FIG. 1 illustrates a preferred embodiment of a micro-piezoelectric resonator of the invention and depicts the major structural elements thereof.

To achieve high resonant amplification (Q), a preferred material for the resonator structure is a single crystal silicon material (SCS).

The resonator element may comprise a single resonator beam element having a first and second terminal portion affixed to an anchor on each of the opposing ends thereof. The anchor is fixedly connected to a base such as a base substrate.

A layer of piezoelectric material (such as aluminum nitrite (AlN), zinc oxide (ZnO) or other suitable materials) is deposited on opposing ends of the resonator element, i.e., the first and second terminal portions as is described more fully in the figures and discussion that follows.

As is known, piezoelectric material is characterized by its unique ability to expand or contract when an electrical voltage is applied across two opposing surfaces of the piezo-material and to generate an electrical voltage when the piezo-material expands and contracts. Metal electrodes are preferably patterned on the opposing surfaces of the piezoelectric material to facilitate connection to an electrical source or for connection to sense a voltage from the material as an output.

The top or upper electrode may be formed by depositing a layer of metal (gold, aluminum, or others) over the AlN layer using an adhesion layer. To promote enhanced adhesion of the metal to AlN, chromium (Cr), platinum (Pt) or other metals may be used as an adhesion layer. For the bottom or lower electrode, single crystal silicon may be used.

To reduce the electrical resistivity of the connection, the single crystal silicon is preferably doped and the surface is implanted with ions to reduce and minimize electrical contact resistance as is known in the semiconductor fabrication arts.

For electrical isolation, single crystal silicon may be disposed on the upper surface on a dielectric layer (e.g., oxide, nitride, or other suitable dielectric material) disposed on the surface of a support or base substrate (typically a silicon material).

FIG. 2 illustrates a cross-section diagram of a preferred embodiment of the resonator element of the invention and depicts a preferred embodiment of the layers of the invention. Table 1 sets forth preferred materials for the resonator element for use in the respective layers of the resonator element of FIG. 2.

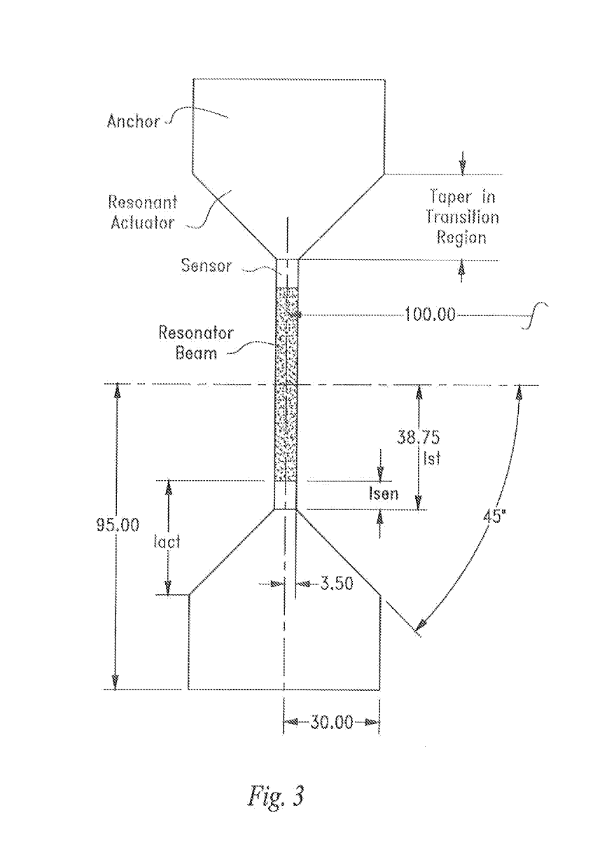

FIG. 3 depicts exemplar dimensions and geometries for a micro-resonator for achieving greater than 1 MHz natural resonance. A taper is provided along one or both of the outer edges of the actuator that connects the first and second terminal portions to the resonator beam. In addition to linear taper, non-linear or curved geometries may also be used in the transition region of the actuator to improve resonator performance and such geometries are expressing within the scope of the claims of the invention herein.

The results of the FEA modeling of resonator design indicate a sensor scale factor of 1.55 mV/V in the illustrated embodiment and represents a relatively high sensitivity. Analysis of inertial sensors that incorporate this form of resonator show increased sensor sensitivity greater than 100 times as compared to other resonant sensor geometries in the prior art.

To achieve high sensitivity in piezoelectric resonators, the mechanical energy produced by the resonating beam must transfer efficiently into the piezoelectric electrodes. The mechanical energy transferred to the resonator beam produces a stress in the piezoelectric material, which in turn generates an electrical voltage that is measured by suitable electronic circuitry.

It has been determined that for very thin resonator beams, an abrupt change in the thickness from the resonator beam to the electrodes, comprise multiple layers of materials, which results in the significant reduction in the efficiency in mechanical energy transfer between the oscillating resonator beam and the connected actuator and sense elements.

For example, in a one micron thickness silicon resonator, the actuator or sense electrode may be as thick as three microns, comprised of, for instance, a one micron layer silicon, a one micron layer piezoelectric material, and one micron metal layer.

The difference between resonator beam and sensor and actuator electrode thickness increases as the resonator beam becomes thinner because the minimum thickness for the piezoelectric and metal layers are generally dictated by design and processing requirements, and by material characteristics.

The increased in the stiffness of the electrodes is due to the increase in structural thickness, but also due to higher stiffness of the piezoelectric material. For example, the Young's Modulus of silicon is approximately 130 MPa, and for AIN is approximately 350 MPa.

The resulting abrupt change in the mechanical stiffness from the resonator beam to the electrodes creates distinct natural resonant modes in which the silicon resonant beam has its own resonant mode that is separate from higher order modes involving the actuator and sensor electrodes. For optimum transducer performance, both the resonator beam and electrodes should ideally displace simultaneously in the same resonant mode. Ideally, this mode should also be the fundamental mode (mode 1) to achieve high-energy output and low signal distortion.

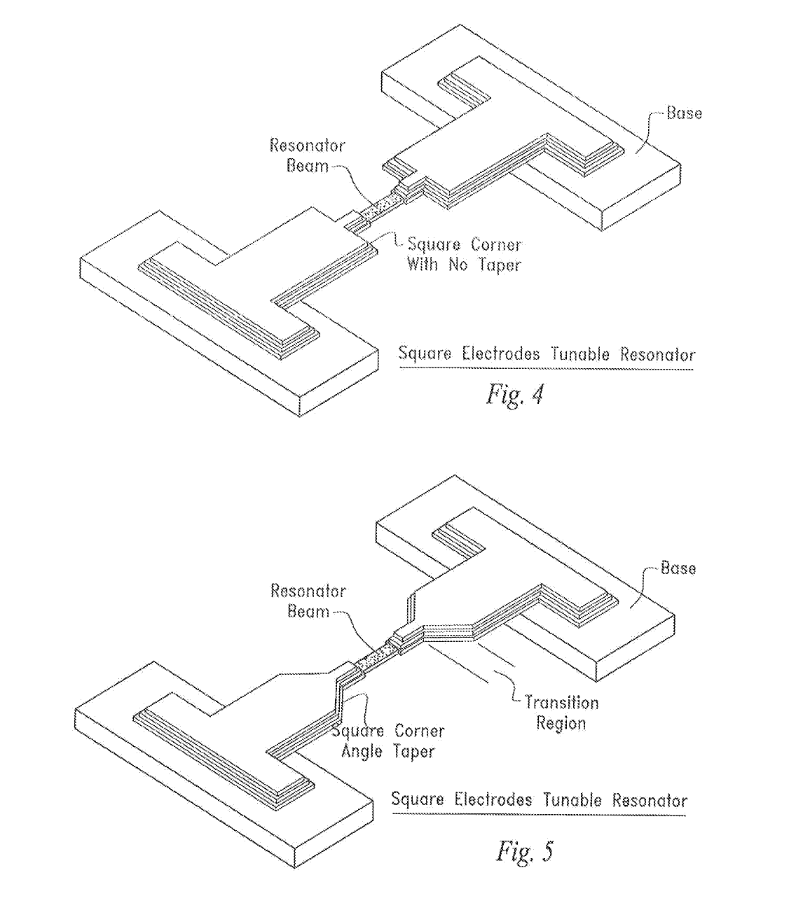

FIG. 4 depicts an electrode design with square corners that tend to result in a fundamental mode shape in which the resonator displacement occurs with little participation from the respective actuator and sensor electrodes.

The instant invention comprises a tapered actuator electrode design that reduces the abrupt changes in the stiffness in the resonator to maximize mechanical energy transfer from the actuator to the resonator beam and to the sensor.

FIG. 4 depicts a preferred tapered actuator and sensor electrode configuration. By adjusting the geometry of the tapered actuator and sensor regions of the device, a single resonant mode is obtained that achieves the desirable criteria discussed above. As noted earlier, a linear taper is not the optimum transition geometry and other non-liner or curved tapers provide higher efficiency.

To evaluate the effectiveness of the tapered electrode versus square electrode, two resonator designs have been modeled and simulated using FEA.

PEA has been performed using the square electrode design and shows qualitatively that Mode 1 consists of primarily movement of the resonator beam, and in Mode 2, the electrode only begin to participate in the resonant mode.

In contrast, in a tapered electrode design, the electrodes participate in Mode 1 as well as in Mode 2 and the participation of the electrodes continues into higher order modes.

A resonator with square electrode design has been built and tested by ISC8 Inc., assignee of the instant application. The measured output of the resonator using a spectrum analyzer shows the first two modes are barely above the noise floor, while Mode 3 is clearly visible. Although Mode 2 shows significant electrode excitation in the FEA, the s-shape resonant of the beam produces lower stress on the electrodes, thus lower electrical output.

FIG. 4 shows the fabricated resonator with the square electrode design.

For some applications, it is desirable to be able to adjust the resonant frequency of the resonator. A prior art (Piazza, Sensors and Actuators, 2004) describes a method for adjusting the frequency of a piezoelectric resonator using an electrostatic force. In the prior art method, an electrode underneath the resonator beam is connected to a DC voltage source, with the resonator beam electrically grounded. The resulting voltage across the beam and the bottom electrode produces an electrostatic force, which bends the beam toward the electrode.

The limitation of this prior art method is that an external electrode is required to be placed underneath the resonant beam. For some applications, an electrode located in close proximity to the resonator beam is not feasible due to the design or processing limitations. A preferred way to stress the resonator beam (for adjusting frequency) is by bending the beam itself. Since the ends of the resonator beam are clamped or affixed to the base, any forced deflection of the beam produces a tension in the beam, thereby negatively affecting the resonant frequency.

A preferred embodiment of a fabricated piezoelectric resonator with a tunable actuator and sensor electrode configuration comprises a larger suspended electrode as the tuning actuator and a relatively smaller suspended electrode as the resonant actuator as well as the sensor.

FIG. 5 depicts an embodiment of a single-beam tunable resonator. A tuning actuator electrode is placed on or proximal the base of the resonator beam that enables stressing the resonator beam. Additional electrodes are provided for actuating and sensing of the resonator movement.

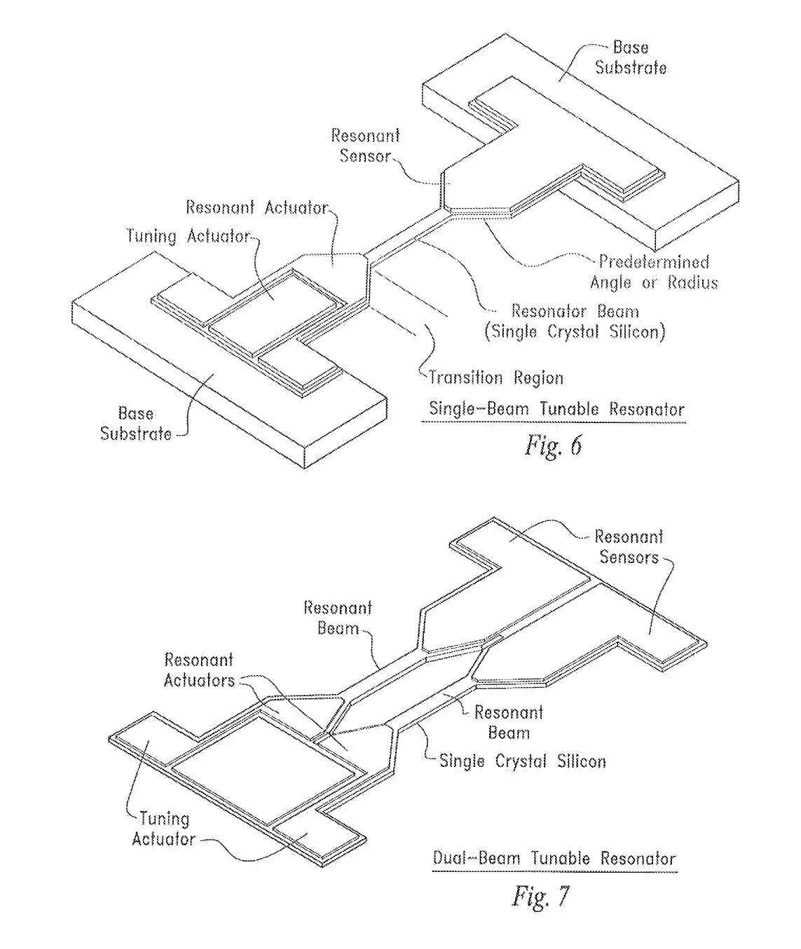

FIG. 6 deceits a dual-beam tunable resonator embodiment of the invention. The advantage of using two beams is that differential sensing is obtained by connecting the output of the resonator to a differential amplifier. Differential sensing provides significantly better suppression of electrical noise and environmental disturbances (temperature, gravity and pressure) than single-ended sensing.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements. The claims are thus to be understood to include what is specifically illustrated and described above, what is conceptually equivalent, what can be obviously substituted and also what essentially incorporates the essential idea of the invention.

We claim:

1. A tunable resonator comprising:
a first terminal portion,
a resonant actuator element,
a sensor element,
a resonator beam in mechanical connection with the resonant actuator element and the sensor element, and,
a second terminal portion.

2. The tunable resonator of claim 1 further comprising a transition region between the resonator beam and the resonant actuator element or the sensor element that is tapered.

3. The tunable resonator of claim 2 wherein the transition region comprises a predetermined angle.

4. The tunable resonator of claim 2 wherein the transition region comprises a predetermined radius.

5. A tunable resonator comprising:
a base substrate,
a first terminal portion,
a resonant actuator element,
a sensor element,
a resonator beam in mechanical connection with the resonant actuator element and the sensor element,
a tuning actuator element, and,
a second terminal portion.

6. The tunable resonator of claim 5 comprising a transition region between the resonator beam and the resonant actuator element or the sensor element that is tapered.

7. The tunable resonator of claim 6 wherein the transition region comprises a predetermined angle.

8. The tunable resonator of claim 6 wherein the transition region comprises a predetermined radius.

9. A dual-beam tunable resonator comprising:
a plurality of resonant actuator elements,
a plurality of sensor elements,
a plurality of resonator beams each of which is in mechanical connection with at least one of the resonant actuator elements and at least one of the sensor elements, and,
a shared tuning actuator configured to permit the common tuning of a resonant frequency of the plurality of resonator beams.

10. The tunable resonator of claim 9 comprising a transition region between at least one resonator beam and at least one of the resonant actuator elements or the sensor elements that is tapered.

11. The tunable resonator of claim 10 wherein at least one of the transition regions comprises a predetermined angle.

12. The tunable resonator of claim 10 wherein at least one of the transition regions comprises a predetermined radius.

13. The tunable resonator of claim 9 further comprising differential amplifier circuitry configured for the differential sensing of the outputs of a plurality of sensor elements.
